(19) United States
(12) Patent Application Publication
(10) Pub. No.: US 2026/0371733 A1
(43) Pub. Date: Nov. 19, 2026

(54) DISPLAY DEVICE, MANUFACTURING METHOD OF DISPLAY DEVICE AND ELECTRONIC DEVICE INCLUDING DISPLAY DEVICE

(71) Applicant: Samsung Display Co., Ltd., Yongin-si (KR)

(72) Inventors: Hyoung Do KIM, Yongin-si (KR); Hyung Jun KIM, Yongin-si (KR); So Young KOO, Yongin-si (KR); Joon Seok PARK, Yongin-si (KR); Ae Ran Song, Yongin-si (KR)

(21) Appl. No.: 19/425,115

(22) Filed: Dec. 18, 2025

(30) Foreign Application Priority Data
May 13, 2025 (KR) 10-2025-0062142

(51) Int. Cl. H10D 86/40; H10D 86/60; H10K 59/12; H10K 59/121

(52) U.S. Cl. CPC H10D 86/441; H10D 86/60; H10K 59/1201; H10K 59/1213

(57) ABSTRACT

A display device includes: a lower transistor; a planarization layer formed on the lower transistor; an upper transistor formed on the planarization layer; an electrode layer formed on the upper transistor; and a conductive layer formed between the planarization layer and the upper transistor and electrically connecting the lower transistor and the electrode layer.

### CROSS-REFERENCE TO RELATED APPLICATION

The present application claims priority to and the benefit of Korean Patent Application No. 10-2025-0062142, filed on May 13, 2025, in the Korean Intellectual Property Office, the entire content of which is incorporated herein by reference.

### BACKGROUND

### 1. Field

One or more embodiments of the present disclosure relate to a display device, a manufacturing method of the display device, and an electronic device including the display device, for example, relate to a display device including a pixel circuit for controlling a light emitting element, a manufacturing method of the display device, and an electronic device including the display device.

### 2. Description of the Related Art

In display devices such as organic light emitting diode (OLED) display devices and/or liquid crystal display devices (LCD), a display substrate that includes, for example, thin film transistors (TFTs) and various wirings is commonly provided. A display structure including electrodes and a light emitting layer may be formed on the display substrate.

For example, an OLED display device may include light emitting elements, each including an organic light emitting layer, and a pixel circuit configured to control the light emitting elements.

### SUMMARY

One or more aspects of embodiments of the present disclosure are directed toward a display device with high resolution and high integration.

One or more aspects of embodiments of the present disclosure are directed toward a manufacturing method of a display device that has high resolution and high integration.

One or more aspects of embodiments of the present disclosure are directed toward an electronic device including a display device that has high resolution and high integration.

However, aspects of the present disclosure are not restricted to the one set forth herein. The above and other aspects of the present disclosure will become more apparent to one of ordinary skill in the art to which the present disclosure pertains by referencing the detailed description of the present disclosure provided herein.

According to one or more embodiments of the present disclosure, a display device includes: a lower transistor; a planarization layer on (e.g., formed on) the lower transistor; an upper transistor on (e.g., formed on) the planarization layer; an electrode layer on (e.g., formed on) the upper transistor; and a conductive layer between (e.g., formed between) the planarization layer and the upper transistor and electrically connecting the lower transistor and the electrode layer.

In one or more embodiments, the conductive layer may include a first connection electrode that penetrates through the planarization layer and is electrically connected to the lower transistor.

In one or more embodiments, the conductive layer may further include a gate lower electrode electrically connected to a gate electrode of the upper transistor.

In one or more embodiments, the display device may further include an insulating layer on (e.g., formed on) the upper transistor to cover the upper transistor, and the electrode layer may include a second connection electrode that penetrates through at least the insulating layer and is electrically connected to the first connection electrode.

In one or more embodiments, the electrode layer may further include a gate connection electrode having one side penetrating through the insulating layer and electrically connected to the gate electrode of the upper transistor.

In one or more embodiments, the conductive layer may further include a gate lower electrode that at least partially overlaps the upper transistor, and the other side of the gate connection electrode may penetrate through the insulating layer and may be electrically connected to the gate lower electrode.

In one or more embodiments, the electrode layer may further include a drain electrode that penetrates through the insulating layer and is electrically connected to a drain region of the upper transistor.

In one or more embodiments, the display device may further include: a lower insulating layer on (e.g., formed on) the lower transistor to cover the lower transistor; and a lower electrode layer on (e.g., formed on) the lower insulating layer, covered by the planarization layer, and electrically connected to the lower transistor, and the first connection electrode may be electrically connected to the lower electrode layer.

In one or more embodiments, the lower electrode layer may include a lower drain electrode that penetrates through the lower insulating layer and is electrically connected to a drain region of the lower transistor.

In one or more embodiments, the lower electrode layer may further include a lower gate connection electrode having one side penetrating through the lower insulating layer and electrically connected to a gate electrode of the lower transistor.

In one or more embodiments, the display device may further include a second gate lower electrode having at least a portion arranged at a lower portion of the lower transistor to overlap the lower transistor, and the other side of the lower gate connection electrode may penetrate through the lower insulating layer and may be electrically connected to the second gate lower electrode.

In one or more embodiments, the planarization layer may include a Spin On Glass (SOG) material.

According to one or more embodiments of the present disclosure, there is provided a manufacturing method of a display device, the manufacturing method including: forming a lower transistor on a substrate; forming a planarization layer on the lower transistor; forming a conductive layer on the planarization layer, the conductive layer penetrating through the planarization layer and being electrically connected to the lower transistor; forming an upper transistor on the conductive layer; and forming an electrode layer electrically connected to the conductive layer on the upper transistor.

In one or more embodiments, the forming of the conductive layer may include: forming a first contact hole penetrating through at least the planarization layer; forming a first metal layer on the planarization layer to fill the first contact hole; and forming the conductive layer by patterning the first metal layer, the conductive layer including a first connection electrode electrically connected to the lower transistor through a contact filling the first contact hole.

In one or more embodiments, in the forming of the conductive layer by patterning the first metal layer, the first connection electrode and a gate lower electrode separated from the first connection electrode may be formed by patterning the first metal layer.

In one or more embodiments, the manufacturing method may further include forming an insulating layer on the upper transistor to cover the upper transistor, and the forming of the electrode layer may include: forming a plurality of contact holes penetrating through at least the insulating layer, the plurality of contact holes at least including a second contact hole extending to the gate lower electrode, a third contact hole extending to a gate electrode of the upper transistor, and a fourth contact hole extending to the first connection electrode; forming a second metal layer on the insulating layer to fill the plurality of contact holes; and forming the electrode layer by patterning the second metal layer, the electrode layer including a gate connection electrode electrically connected to the gate lower electrode through a contact filling the second contact hole and electrically connected to the gate electrode of the upper transistor through a contact filling the third contact hole, and a second connection electrode electrically connected to the first connection electrode by a contact filling the fourth contact hole.

In one or more embodiments, in the forming of the plurality of contact holes, the plurality of contact holes may further include a fifth contact hole that penetrates through at least the insulating layer and extends to a drain region of the upper transistor, and in the forming of the electrode layer by patterning the second metal layer, the electrode layer may include a drain electrode electrically connected to the drain region of the upper transistor by a contact filling the fifth contact hole.

In one or more embodiments, the manufacturing method may further include: forming a lower insulating layer on the lower transistor to cover the lower transistor; forming a sixth contact hole penetrating through the lower insulating layer and extending to the lower transistor; forming a third metal layer on the lower insulating layer to fill the sixth contact hole; and forming a lower transistor connection electrode electrically connected to the lower transistor by patterning the third metal layer, and the first contact hole may extend to the lower transistor connection electrode.

According to one or more embodiments of the present disclosure, an electronic device includes: a display device; a memory; and a processor configured to control an operation of the display device by executing data included (e.g., stored) in the memory, wherein the display device includes: a lower transistor; a planarization layer on (e.g., formed on) the lower transistor; an upper transistor on (e.g., formed on) the planarization layer; an electrode layer on (e.g., formed on) the upper transistor; and a conductive layer between (e.g., formed between) the planarization layer and the upper transistor and electrically connecting the lower transistor and the electrode layer.

In one or more embodiments, the electronic device may include at least one of virtual reality or augmented reality glasses, a smartphone, a tablet PC, a laptop, a TV, a desk monitor, smart glasses, a head-mounted display, a smart watch, or a vehicle display.

According to one or more embodiments of the present disclosure, in the pixel circuit having a structure in which a plurality of transistors are stacked with a planarization layer interposed therebetween, a connection electrode connected to an electrode of a lower transistor may be connected through an electrode layer on an upper transistor.

Therefore, the degree of freedom of wiring for the upper and lower transistors may be improved, thereby implementing high integration and high resolution.

In addition, for example, by configuring the conductive layer to include at least one connection electrode penetrating the planarization layer and by arranging the electrode layer to include a corresponding connection electrode, the disclosed structure enables electrical coupling between the lower transistor and the electrode layer without requiring lateral routing space. This vertical integration reduces parasitic resistance, simplifies interconnect layout, and allows the upper and lower transistors to operate cooperatively within a compact pixel circuit. As a result, the architecture supports higher aperture ratios and improved display performance while maintaining compatibility with suitable thin-film transistor fabrication processes.

However, the effects and benefit according to embodiments of the present disclosure are not limited to those exemplified above and one or more suitable other effects and benefit are incorporated herein.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent by describing in more detail embodiments thereof with reference to the accompanying drawings, in which:

FIG. 1 is a schematic plan view of a display device according to one or more embodiments of the present disclosure;

FIG. 2 is a pixel circuit diagram of a pixel according to one or more embodiments of the present disclosure;

FIG. 3 is a cross-sectional view of a display device according to one or more embodiments of the present disclosure;

FIGS. 4A − 4H are views illustrating a manufacturing method of a display device according to one or more embodiments of the present disclosure;

FIG. 5 is a cross-sectional view of a display device according to one or more embodiments of the present disclosure;

FIG. 6 is an exploded perspective view illustrating an electronic device according to one or more embodiments of the present disclosure;

FIG. 7 is a block diagram of an electronic device according to one or more embodiments of the present disclosure; and

FIG. 8 illustrates schematic views of electronic devices according to one or more embodiments of the present disclosure.

### DETAILED DESCRIPTION

The present disclosure will now be described more fully hereinafter with reference to the accompanying drawings, in which one or more example embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that if (e.g., when) an element or a layer is referred to as being "on" another element or layer, it may be directly on the other element or layer, or one or more intervening layers may also be present therebetween. In contrast, if (e.g., when) an element is referred to as being "directly on" another element, there may be no intervening element present therebetween. The same or like reference numbers indicate the same or like components throughout the disclosure.

It will be understood that, although the terms "first," "second," and/or the like may be used herein to describe one or more suitable elements, these elements should not be limited by these terms. These terms are only used to distinguish one element from another element. For instance, a first element discussed herein could be termed a second element without departing from the teachings of the present disclosure. Similarly, the second element could be termed the first element.

Features of each of one or more suitable embodiments of the present disclosure may be partially or entirely combined with each other and may technically variously interwork with each other, and respective embodiments may be implemented independently of each other or may be implemented together in association with each other.

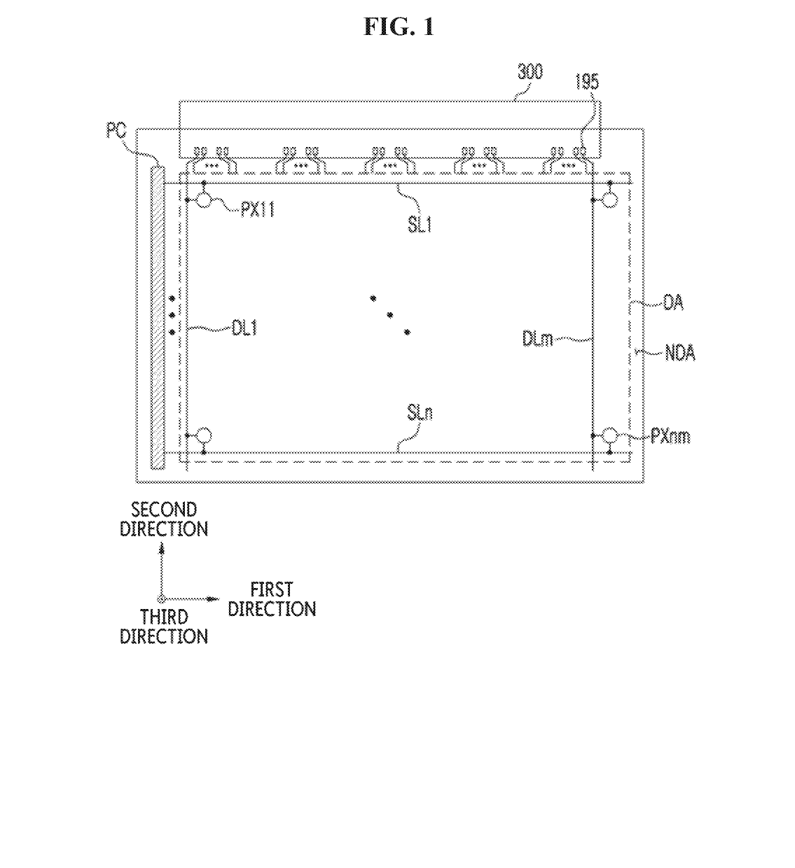

FIG. 1 is a schematic plan view of a display device according to one or more embodiments of the present disclosure. For example, FIG. 1 is a plan view illustrating a pixel arrangement of the display device according to one or more embodiments.

In FIG. 1, a first direction and a second direction may refer to two directions that are parallel to a display surface of the display device and normal (e.g., perpendicular) to each other. For example, the first direction may correspond to an X direction (row direction) and the second direction may correspond to a Y direction (column direction) of the display device. The third direction may be perpendicular to the first direction and the second direction. The third direction may correspond to a Z direction (thickness direction) of the display device.

In the other accompanying drawings, the definition of directions described above may be equally applied.

Referring to FIG. 1, a plurality of pixels PX11 to PXnm may be arranged in a display area DA of the display device.

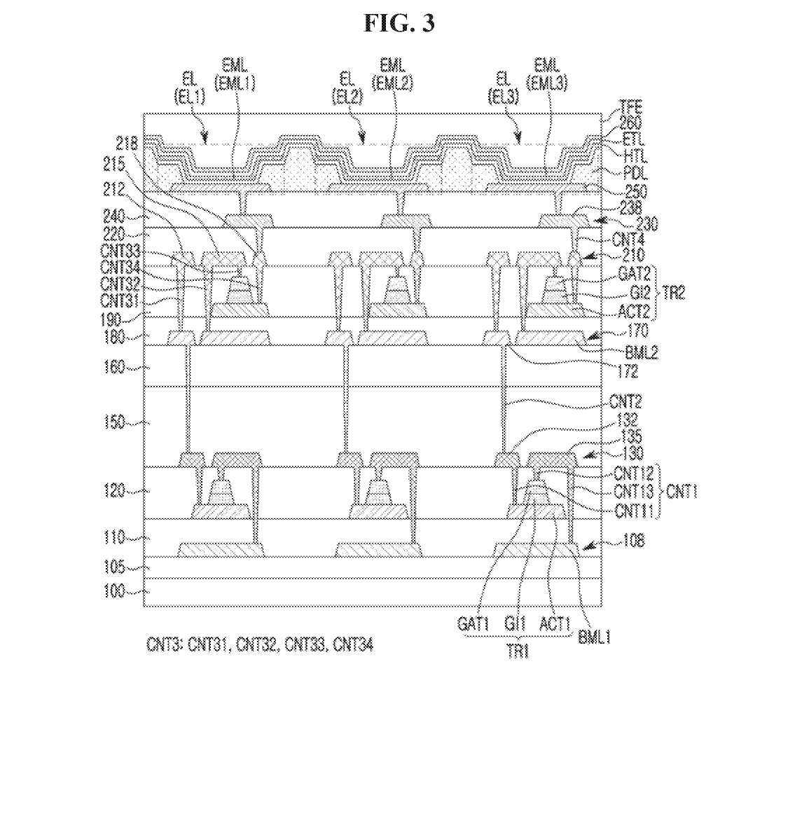

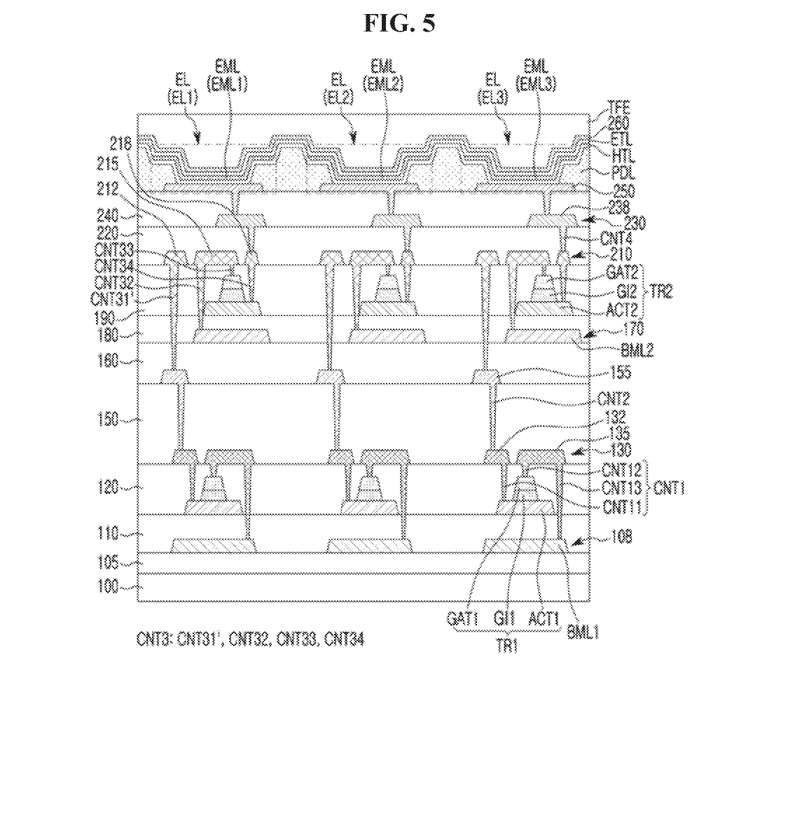

According to one or more embodiments, a pixel circuit including scan lines (or gate lines) SL1 to SLn forming first to n-th rows and data lines DL1 to DLm forming first to m-th columns may be arranged on a base substrate 100 (see FIG. 3 and FIG. 5) of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a light emitting element and a pixel circuit including a transistor as described below. In one or more embodiments, the pixel circuit may further include wirings such as a power line, a ground line, and/or the like.

It is illustrated in FIG. 1 that the data lines DL1 to DLm extend in the second direction and the scan lines SL1 to SLn extend in the first direction, but embodiments of the present disclosure are not necessarily limited thereto.

A peripheral circuit PC may be arranged in a non-display area NDA corresponding to a peripheral area of the display area DA. For example, in one or more embodiments, the peripheral circuit PC may include a gate driving circuit. The gate driving circuit may be integrated into the display device through an oxide silicon gate driver circuit (OSG) process and/or a polysilicon gate driver circuit (PSG) process.

The peripheral circuit PC may further include a data driver, a gate driver, a light emitting driver, a power voltage generator, a timing controller, and/or the like.

The display device may further include a printed circuit board 300. Pad portions 195 of the pixel circuit may be bonded to a (e.g., one) side of the non-display area NDA. The printed circuit board 300 may be electrically connected to the pixel circuit through the pad portions 195. For example, in one or more embodiments, the printed circuit board 300 may be electrically connected to the pad portions 195 through a heat-pressing process using a conductive intermediary structure such as an anisotropic conductive film (ACF).

An integrated circuit (IC), such as a data driving circuit, may be arranged on the printed circuit board 300. In one or more embodiments, an integrated circuit (IC) chip may be mounted on the printed circuit board 300 in the form of a chip-on-film (COF).

Hereinafter, the configurations/structures of the display device of embodiments of the present disclosure may be described using an organic light emitting display device as an example. However, the display device disclosed in the present disclosure may also be applied to one or more other suitable types (kinds) of display devices such as an inorganic light emitting display device, a quantum dot light emitting display device, and/or the like.

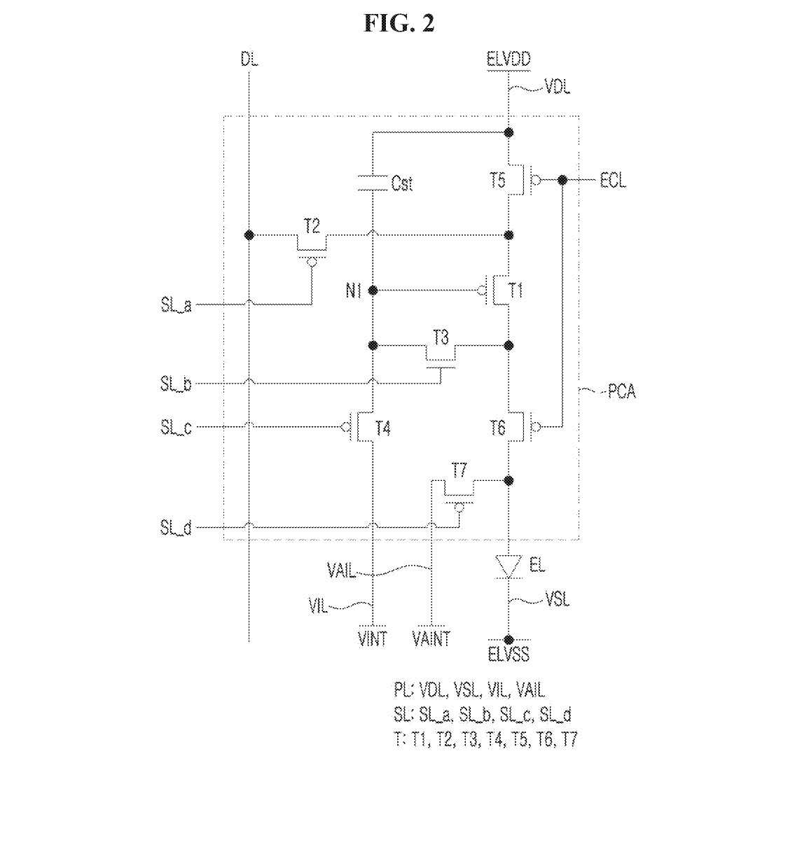

FIG. 2 is a circuit diagram of a display device according to one or more embodiments of the present disclosure.

FIG. 2 illustrates a configuration of a pixel circuit PCA and wirings connected to the pixel circuit PCA. However, the configuration of the pixel circuit and the type (kind) and number of wirings connected to the pixel circuit may be varied according to display characteristics of the display device.

The pixel circuit PCA may include first to seventh transistors T1 to T7. In one or more embodiments, scan lines SL connected to a pixel in FIG. 2 may include a first scan line SL_a, a second scan line SL_b, a third scan line SL_c, and a fourth scan line SL_d, and power lines PL connected to the pixel in FIG. 2 may include a first pixel power line VDL, a second pixel power line VSL, a first initialization power line VIL, and a second initialization power line VAIL. The pixel in FIG. 2 may be further connected to an emission control line ECL.

Referring to FIG. 2, the pixel may include at least one light emitting element EL and the pixel circuit PCA connected to the light emitting element EL.

The light emitting element EL may be connected between the second pixel power line VSL to which a second pixel power voltage ELVSS is applied and the pixel circuit PCA. In one or more embodiments, the second pixel power voltage ELVSS may be a low-potential pixel driving voltage. The light emitting element EL, which is a light source of the pixel, may be to emit light by receiving a driving current supplied from the pixel circuit PCA.

The light emitting element EL may be, but is not limited to, an organic light emitting diode. For example, in one or more embodiments, the light emitting element EL may be an inorganic light emitting element, a quantum dot light emitting element, or another type (kind) of light emitting element.

The pixel circuit PCA may control the light emitting timing and luminance of the light emitting element EL by controlling the driving current supplied to the light emitting element EL. The pixel circuit PCA may include at least one transistor T and a capacitor Cst. In one or more embodiments, the pixel circuit PCA may include a pixel transistor T including first to seventh transistors T1 to T7.

The first transistor T1 may include a gate electrode connected to the first node N1, a first electrode electrically connected to the first pixel power line VDL through the fifth transistor T5, and a second electrode electrically connected to the light emitting element EL through the sixth transistor T6. One selected from among the first electrode and the second electrode may be a source electrode, and the other may be a drain electrode. The first transistor T1 may control a source-drain current (hereinafter referred to as “driving current”) flowing between the first electrode and the second electrode according to a voltage applied to the gate electrode (e.g., a voltage of the first node N1 corresponding to a voltage of the data signal). For example, the first transistor T1 may be a driving transistor of the pixel.

The second transistor T2 may include a gate electrode connected to the first scan line SL_a, a first electrode connected to the data line DL, and a second electrode connected to the first electrode of the first transistor T1. The second transistor T2 may be turned on by a first scan signal supplied to the first scan line SL_a to electrically connect the first electrode of the first transistor T1 and the data line DL. When the second transistor T2 is turned on, the voltage of a data signal supplied to the data line DL may be applied to the first electrode of the first transistor T1.

The third transistor T3 may include a gate electrode connected to the second scan line SL_b, a first electrode connected to the second electrode of the first transistor T1, and a second electrode connected to the gate electrode of the first transistor T1 (or the first node N1). The third transistor T3 may be turned on by a second scan signal supplied to the second scan line SL_b to electrically connect the gate electrode and the second electrode of the first transistor T1. When the third transistor T3 is turned on, the first transistor T1 may be driven as a diode.

The fourth transistor T4 may include a gate electrode connected to the third scan line SL_c, a first electrode connected to the gate electrode of the first transistor T1, and a second electrode connected to the first initialization power line VIL. The fourth transistor T4 may be turned on by a third scan signal supplied to the third scan line SL_c to electrically connect the gate electrode of the first transistor T1 and the first initialization power line VIL. When the fourth transistor T4 is turned on, a first initialization voltage VINT (e.g., a gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on by an emission control signal supplied to the emission control line ECL to electrically connect the first electrode of the first transistor T1 and the first pixel power line VDL to which a first pixel power voltage ELVDD is applied. When the fifth transistor T5 is turned on, the first pixel power voltage ELVDD may be applied to the first electrode of the first transistor T1. In one or more embodiments, the first pixel power voltage ELVDD may be a high-potential pixel driving voltage.

The sixth transistor T6 may include a gate electrode connected to the emission control line ECL, a first electrode connected to the second electrode of the first transistor T1, and a second electrode connected to the light emitting element EL. The sixth transistor T6 may be turned on by the emission control signal supplied to the emission control line ECL to electrically connect the first transistor T1 and the light emitting element EL. When both (e.g., simultaneously) the fifth transistor T5 and the sixth transistor T6 are turned on, a driving current having a magnitude corresponding to the voltage of the gate electrode of the first transistor T1 may flow to the light emitting element EL.

The seventh transistor T7 may include a gate electrode connected to the fourth scan line SL_d, a first electrode connected to an anode electrode of the light emitting element EL, and a second electrode connected to the second initialization power line VAIL. The seventh transistor T7 may be turned on by a fourth scan signal supplied to the fourth scan line SL_d to electrically connect the anode electrode of the light emitting element EL and the second initialization power line VAIL. The fourth scan signal may be the same signal as the first scan signal or a different signal from the first scan signal. When the seventh transistor T7 is turned on, a second initialization voltage VAINT (e.g., an anode initialization voltage) of the second initialization power line VAIL may be applied to the anode electrode of the light emitting element EL.

The capacitor Cst may be connected between the gate electrode of the first transistor T1 and the first pixel power line VDL. The capacitor Cst may be charged with a voltage corresponding to the voltage of the data signal applied to the gate electrode of the first transistor T1.

An active layer (e.g., a semiconductor pattern including a channel region) of each of the pixel transistors T (e.g., the first to seventh transistors T1 to T7) may include a (e.g., one) semiconductor material selected from among polysilicon, amorphous silicon, and oxide semiconductors. In one or more embodiments, some and other of the pixel transistors T may be formed as different conductive types (kinds) of transistors. In one or more embodiments, some and other of the pixel transistors T may include different types (kinds) of semiconductor materials.

For example, in one or more embodiments, the first, second, fifth, sixth, and seventh transistors T1, T2, T5, T6, and T7 may be formed as P-type (kind) transistors (e.g., P-type (kind) MOSFETs) each including an active layer including polysilicon, and the third and fourth transistors T3 and T4 may be formed as N-type (kind) transistors (e.g., N-type (kind) MOSFETs) each including an active layer including an oxide semiconductor. In one or more embodiments, the transistors each including an active layer including polysilicon and the transistors each including an active layer including an oxide semiconductor may be arranged in different layers within a circuit layer 120 (see FIG. 3 and FIG. 5).

FIG. 3 is a schematic cross-sectional view of the display device according to one or more embodiments of the present disclosure. FIG. 3 illustrates a cross-sectional view cut along the thickness direction (the third direction) of FIG. 1 to include three light emitting elements.

Referring to FIG. 3 in conjunction with FIG. 1, the display device may include a base substrate 100, a pixel circuit, and a light emitting element EL.

The base substrate 100 may be provided as a back-plane substrate of the display device. As the base substrate 100, a glass substrate or a plastic substrate may be used. In one or more embodiments, the base substrate 100 may include a polymer material having transparency and flexibility. In these embodiments, the base substrate 100 may be employed in a transparent flexible display device.

For example, in one or more embodiments, the base substrate 100 may include a polymer material such as polyimide, polysiloxane, an epoxy resin, an acrylic resin, and/or polyester. In one or more embodiments, the base substrate 100 may include polyimide.

A barrier layer 105 may be arranged on the base substrate 100. The barrier layer 105 may block moisture permeating through the base substrate 100 and may block diffusion of impurities between the base substrate 100 and a structure formed on the base substrate 100. The barrier layer 105 may be entirely formed across the display area DA and the non-display area NDA of the base substrate 100, and may entirely cover an upper surface of the base substrate 100.

The barrier layer 105 may include at least one inorganic film including an inorganic insulating material (e.g., silicon nitride, silicon oxide, silicon oxynitride, titanium oxide, aluminum oxide, and/or other inorganic insulating materials). These may be used alone or in combination of two or more. In one or more embodiments, the barrier layer 105 may have a laminated structure including a silicon oxide film and a silicon nitride film.

In one or more embodiments, the barrier layer 105 may include an organic layer and may have a multi-layer structure of an organic layer and an inorganic layer.

The pixel circuit may include wirings including the scan lines and the data lines as described with reference to FIGS. 1 and 2, and transistors electrically interacting with the wirings. The transistors may be electrically connected to the light emitting element EL.

A first lower conductive layer 108 may be arranged on the barrier layer 105. The first lower conductive layer 108 may include a first lower metal layer BML1 overlapping a first active layer ACT1 of at least one lower transistor TR1. It is illustrated in FIG. 3 that the first lower metal layer BML1 is arranged to overlap only the first active layer ACT1 of the lower transistor TR1, but embodiments of the present disclosure are not limited thereto. For example, in one or more embodiments, the first lower metal layer BML1 may be patterned to an appropriate or suitable size and/or shape as needed, or may be arranged on (e.g., across) the entire surface of the pixel circuit. In one or more embodiments, the first lower metal layer BML1 may also be arranged only in a portion of the pixel area so as to overlap the lower transistor TR1. In one or more embodiments, the first lower metal layer BML1 may be utilized as a light blocking pattern and/or a back-gate electrode of at least one lower transistor TR1.

It is illustrated in FIG. 3 that the first lower conductive layer 108 includes only the first lower metal layer BML1, but, in one or more embodiments, the first lower conductive layer 108 may further include other configurations as needed.

A first buffer layer 110 may be arranged on the barrier layer 105 to cover the first lower conductive layer 108. The first buffer layer 110 may include at least one inorganic film including an inorganic insulating material.

The lower transistor TR1 may include an active layer ACT1, a gate insulating layer GI1, and a gate electrode GAT1.

The active layer ACT1 of the lower transistor TR1 may be arranged on the first buffer layer 110 and may be repeatedly/regularly arranged for each pixel. In one or more embodiments, the active layer ACT1 of the lower transistor TR1 may include a silicon compound such as polysilicon or amorphous silicon. Some areas of the active layer ACT1 of the lower transistor TR1 may be doped with p-type (kind) or n- type (kind) dopants, and may include a source region, a drain region, and a channel region.

In one or more embodiments, the active layer ACT1 of the lower transistor TR1 may include an oxide semiconductor such as indium gallium zinc oxide (IGZO), zinc tin oxide (ZTO), and/or indium tin zinc oxide (ITZO).

The gate insulating layer GI1 of the lower transistor TR1 may be formed on the active layer ACT1, and the gate electrode GAT1 may be laminated on the gate insulating layer GI1. As illustrated in FIG. 3, in one or more embodiments, the gate insulating layer GI1 of the lower transistor TR1 may be formed in a pattern shape that partially covers each of the active layers ACT1 of the plurality of lower transistors TR1. In one or more embodiments, the gate insulating layer GI1 may be continuously and commonly provided for the plurality of transistors or the plurality of pixels.

The gate electrode GAT1 of the lower transistor TR1 may overlap the channel region of the active layer ACT1 in the third direction. A scan signal may be transmitted from a scan line through the gate electrode GAT1 of the lower transistor TR1.

The gate insulating layer GI1 of the lower transistor TR1 may include an inorganic insulating material such as silicon oxide, silicon nitride, silicon oxynitride, and/or the like.

A first interlayer insulating layer 120 covering the active layer ACT1, the gate insulating layer GI1, and the gate electrode GAT1 of the lower transistor TR1 may be formed on the first buffer layer 110. A first connection electrode layer 130 that is in contact with or electrically connected to the lower transistor TR1 may be formed on the first interlayer insulating layer 120.

The first interlayer insulating layer 120 may include an inorganic insulating material such as silicon oxide, silicon nitride, silicon oxynitride, and/or the like. The first interlayer insulating layer 120 may be formed as a single-layer structure or a multi-layer structure including different materials.

The first connection electrode layer 130 may include at least one of a first source/drain electrode 132 and a first gate connection electrode 135. Hereinafter, one or more embodiments will be described in which the first connection electrode layer 130 includes a first source/drain electrode 132 and a first gate connection electrode 135, and the first source/drain electrode 132 is a drain electrode.

The first source/drain electrode 132 may penetrate through the first interlayer insulating layer 120 and be connected to the active layer ACT1 of the lower transistor TR1. The first source/drain electrode 132 may be a source electrode connected to or in contact with the source region of the active layer ACT1 of the lower transistor TR1, or a drain electrode connected to or in contact with the drain region of the active layer ACT1 of the lower transistor TR1. In FIG. 3, only one first source/drain electrode 132 is illustrated in one lower transistor TR1, but two first source/drain electrodes may be in contact with or connected to the source region and the drain region of the active layer ACT1 of one transistor TR1, respectively.

The first gate connection electrode 135 may have one side penetrating through the first interlayer insulating layer 120 and in contact with or connected to the gate electrode GAT1 of the lower transistor TR1, and the other side penetrating through the first interlayer insulating layer 120 and the first buffer layer 110 and in contact with or connected to the first lower metal layer BML1. Accordingly, a gate voltage of the lower transistor TR1 may be controlled or selected by a voltage applied through the first lower metal layer BML1.

The gate electrode GAT1 and the first connection electrode layer 130 (the first source/drain electrode 132 and the first gate connection electrode 135) of the lower transistor TR1 may independently include a metal such as silver (Ag), magnesium (Mg), aluminum (Al), tungsten (W), copper (Cu), nickel (Ni), chromium (Cr), molybdenum (Mo), titanium (Ti), platinum (Pt), tantalum (Ta), neodymium (Nd), scandium (Sc), and/or the like, an alloy thereof, or a nitride thereof. In one or more embodiments, the gate electrode GAT1 and/or the first connection electrode layer 130 of the lower transistor TR1 may each independently have a multi-layer structure including different metal layers.

A planarization layer 150 covering the first connection electrode layer 130 may be formed on the first interlayer insulating layer 120.

In one or more embodiments, the planarization layer 150 may include a Spin On Glass (SOG) material. The SOG material, which is a composite material of organic and inorganic materials with a mixed cage-network structure, is a material that may be converted into SiO₂ through annealing at temperatures of about 400°C or more. If (e.g., when) the planarization layer 150 includes the SOG material, high-temperature heat resistance characteristics may be improved.

In one or more embodiments, the SOG material may include silica and an organic material. In this regard, the organic material may be a siloxane compound and/or a photosensitive polyimide (PSPI). In one or more embodiments, the SOG material may be selected from the group consisting of silicate, siloxane, methyl silsesquioxane (MSQ), hydrogen silsesquioxane (HSQ), perhydropolysilazane ((SiH₂NH)ₙ)), polysilazane, and a mixture thereof.

In one or more embodiments, the planarization layer 150 may include an organic material such as polyimide, an epoxy resin, an acrylic resin, polyester, a siloxane resin, a benzocyclobutene (BCB) resin, and/or the like.

In a structure where an upper transistor TR2 is laminated on the lower transistor TR1, it becomes more difficult to planarize the layers as a distance from an upper portion is shorter, the laminating may be formed in a reverse taper shape. Accordingly, a short circuit may occur between an active layer ACT2 and a gate electrode GAT2 of the upper transistor TR2. The planarization layer 150 may be formed to a considerable thickness, for example, in the range of about 5 kÅ to about 7 kÅ, so that the upper transistor TR2 may be formed to be flat without being affected by the lower transistor TR1 when being laminated.

A second interlayer insulating layer 160 may be formed on the planarization layer 150.

The second interlayer insulating layer 160 may include an inorganic insulating material such as silicon oxide, silicon nitride, silicon oxynitride, and/or the like. The second interlayer insulating layer 160 may be formed as a single-layer structure or a multi-layer structure including different materials.

A second lower conductive layer 170 may be formed on the second interlayer insulating layer 160.

The second lower conductive layer 170 may include a second lower metal layer BML2 overlapping an active layer ACT2 of at least one upper transistor TR2.

In one or more embodiments, the second lower conductive layer 170 may include a first connection electrode 172.

The first connection electrode 172 may penetrate through the second interlayer insulating layer 160 and the planarization layer 150 and be connected to the first source/drain electrode 132. In one or more embodiments, the first connection electrode 172 may also be connected to a portion of the first connection electrode layer 130 other than the first source/drain electrode 132, for example, the first gate connection electrode 135. In one or more embodiments, a plurality of first connection electrodes 172 may also be connected to each portion of the first connection electrode layer 130, for example, the first source/drain electrode 132 and the first gate connection electrode 135.

A contact hole CNT2 may be connected to the first connection electrode layer 130. Although FIG. 3 illustrates that the contact hole CNT2 is connected to the first source/drain electrode 132 of the first connection electrode layer 130, embodiments of the present disclosure are not limited thereto, and the contact hole CNT2 may also be connected to another portion of the first connection electrode layer 130, for example, the first gate connection electrode 135.

A second buffer layer 180 may be arranged on the second lower conductive layer 170 to cover the second lower conductive layer 170. The second buffer layer 180 may include at least one inorganic film including an inorganic insulating material.

An upper transistor TR2 may be formed on the second buffer layer 180. The upper transistor TR2 may include an active layer ACT2, a gate insulating layer GI2, and a gate electrode GAT2. Because the structure of the upper transistor TR2 is similar to that of the lower transistor TR1 described above, a duplicate description thereof is repeated herein for conciseness.

A third interlayer insulating layer 190 covering the active layer ACT2, the gate insulating layer GI2, and the gate electrode GAT2 may be formed on the second buffer layer 180.

A second connection electrode layer 210 that is in contact with or electrically connected to the second lower conductive layer 170 may be formed on the third interlayer insulating layer 190. The second connection electrode layer 210 may include a second connection electrode 212 that at least partially overlaps the first connection electrode 172. The second connection electrode layer 210 may include a second gate connection electrode 215 overlapping the gate electrode GAT2 of the upper transistor TR2, and/or a second source/drain electrode 218 overlapping a source region or drain region of the upper transistor TR2. The second connection electrode layer 210 may be in contact with or electrically connected to the upper transistor TR2 through the second gate connection electrode 215 and/or the second source/drain electrode 218.

The second connection electrode 212 may penetrate through the third interlayer insulating layer 190 and the second buffer layer 180 and be electrically connected to the first connection electrode 172. As described above, the first connection electrode 172 is electrically connected to the first connection electrode layer 130, and the first connection electrode layer 130 is electrically connected to the lower transistor TR1. Accordingly, the second connection electrode 212 may be electrically connected to the lower transistor TR1.

One side of the second gate connection electrode 215 may be electrically connected to the gate electrode GAT2 of the upper transistor TR2 by penetrating through the third interlayer insulating layer 190. The other side of the second gate connection electrode 215 may be electrically connected to the second lower metal layer BML2 by penetrating through the third interlayer insulating layer 190 and the second buffer layer 180. Accordingly, the gate electrode GAT2 of the upper transistor TR2 and the second lower metal layer BML2 may be electrically connected through the second gate connection electrode 215. A gate voltage may be applied to the second lower metal layer BML2 through a wiring not illustrated.

The second source/drain electrode 218 may penetrate through the third interlayer insulating layer 190 and be electrically connected to the source region or the drain region of the upper transistor TR2. In FIG. 3, the second source/drain electrode 218 is illustrated as being connected to only one of the source region or the drain region of the upper transistor TR2. However, embodiments of the present disclosure are not limited thereto, and a plurality of second source/drain electrodes 218 may also be connected to each of the source region and the drain region of the upper transistor TR2.

Contact holes CNT31 and CNT32 may be each connected to the second lower conductive layer 170. The contact hole CNT31 may be in contact with the first connection electrode 172. The contact hole CNT32 may be in contact with the second lower metal layer BML2. Contact holes CNT33 and CNT34 may be each in contact with the second transistor TR2. The contact hole CNT33 may be in contact with the gate electrode GAT2 of the upper transistor TR2. The contact hole CNT34 may be in contact with the source region or the drain region of the upper transistor TR2.

A first via layer 220 may be formed on the third interlayer insulating layer 190 to cover the second connection electrode layer 210.

A third connection electrode layer 230 may be formed by partially etching the first via layer 220. The third connection electrode layer 230 may include a source/drain connection electrode 238. The third connection electrode layer 230 may at least partly overlap the second source/drain electrode 218. A contact hole CNT4 may be in contact with the second connection electrode layer 210. In one or more embodiments, the contact hole CNT4 may be in contact with the second source/drain electrode 218.

A second via layer 240 may be formed on the first via layer 220 to cover the third connection electrode layer 230. The second via layer 240 may accommodate a via portion that electrically connects a pixel electrode 250 and the source/drain connection electrode 238.

In one or more embodiments, the first via layer 220 and the second via layer 240 may each independently include an organic material such as polyimide, an epoxy resin, an acrylic resin, polyester, a siloxane resin, a benzocyclobutene (BCB) resin, and/or the like.

The pixel electrode 250 may be formed for each pixel and may be electrically connected to the upper transistor TR2. The pixel electrode 250 may be formed on the second via layer 240 and electrically connected to the second source/drain electrode 218.

In one or more embodiments, the pixel electrode 250 may be provided as an anode and include a high work function conductive material that promotes hole injection. In one or more embodiments, the pixel electrode 250 may be provided as a transmissive electrode. The pixel electrode 250 may include a transparent conductive oxide such as indium tin oxide (ITO), indium zinc oxide (IZO), zinc oxide (ZnO), indium tin zinc oxide (ITZO), and/or the like.

In one or more embodiments, the pixel electrode 250 may be provided as a semi-transmissive electrode or a reflective electrode. The pixel electrode 250 may include a metal selected from the group consisting of Ag, Mg, Cu, Al, Pt, Pd, Au, Ni, Nd, Ir, Cr, Li, Ca, LiF, Mo, Ti, W, In, Sn, and Zn, or an alloy of two or more metals thereof.

The pixel electrode 250 may have a single-layer structure or a multi-layer structure. For example, in one or more embodiments, the pixel electrode 250 may have a three-layer structure of ITO/Ag/ITO.

A pixel defining film PDL that exposes an upper surface of the pixel electrode 250 may be formed on the second via layer 240. As the pixel defining film PDL is formed, an opening that at least partially exposes the upper surface of the pixel electrode 250 may be formed, and a pixel area may be defined by the opening. The pixel defining film PDL may cover a peripheral portion of the pixel electrode 250.

For example, the pixel area or light emitting area may be defined by sidewalls of the pixel defining film PDL. As illustrated in FIG. 3, a first pixel including a second transistor TR2 and a first light emitting element EL1 on the left, a second pixel including a second transistor TR2 and a second light emitting element EL2 in the middle, and a third pixel including a second transistor TR2 and a third light emitting element EL3 on the right may be separated and defined from one another by the pixel defining film PDL.

In one or more embodiments, the first pixel, the second pixel, and the third pixel may correspond to a red pixel, a green pixel, and a blue pixel, respectively.

The pixel defining film PDL may include an organic material such as, for example, a polysiloxane resin, a polyimide resin, or an acrylic resin. In one or more embodiments, the pixel defining film PDL may also include a coloring agent, such as a black pigment/dye, dispersed within the resin material. In one or more embodiments, the pixel defining film PDL may include an inorganic layer such as a silicon oxide film and/or a silicon nitride film.

In one or more embodiments, the pixel defining film PDL may have a step structure as illustrated in FIG. 3.

A light emitting layer EML may be arranged on the exposed surface of the pixel electrode 250. In one or more embodiments, the light emitting layer EML may include an organic light emitting material that is independently patterned for each of the red pixel, the green pixel, and the blue pixel to generate light of different colors for each pixel.

The light emitting layer EML may include a first light emitting layer EML1 included in the first pixel and including a red organic light emitting material (e.g., emitting red color light), a second light emitting layer EML2 included in the second pixel and including a green organic light emitting material (e.g., emitting green color light), and a third light emitting layer EML3 included in the third pixel and including a blue organic light emitting material (e.g., emitting blue color light).

For example, the organic light emitting material may include a host material that is excited by holes and electrons, and a dopant material that increases emission efficiency through absorption and emission of energy.

In one or more embodiments, a hole transporting layer HTL may be arranged between the pixel electrode 250 and the light emitting layer EML. An electron transporting layer ETL may be arranged on the light emitting layer EML.

The hole transporting layer HTL and the electron transporting layer ETL may each commonly and continuously extend across the plurality of light emitting elements EL and pixels.

For example, in one or more embodiments, the hole transporting layer HTL may include a hole transporting material such as m-MTDATA(4,4',4"-[tris(3-methylphenyl)phenylamino] triphenylamine), TDATA(4,4'4"-tris(N,N-diphenylamino)triphenylamine), 2-TNATA(4,4',4"-tris[N-(2-naphthyl)-N-phenylamino]- triphenylamine), NPB(N,N'-di(naphthalen-1-yl)-N,N'-diphenyl-benzidine), TPD(N,N'-bis(3-methylphenyl)-N,N'-diphenyl-[1,1'-biphenyl]-4,4'-diamine), TCTA(4,4',4"-tris(N-carbazolyl)triphenylamine), and/or PEDOT/PSS(poly(3,4-ethylenedioxythiophene)/poly(4-styrenesulfonate)).

For example, in one or more embodiments, the electron transporting layer ETL may include an electron transporting material such as an anthracene-based compound, Alq₃(tris(8-hydroxyquinolinato)aluminum), TPBi(1,3,5-Tri(1-phenyl-1H-benzo[d]imidazol-2-yl)benzene), BCP(2,9-dimethyl-4,7-diphenyl-1,10-phenanthroline), Bphen(4,7-diphenyl-1,10-phenanthroline), TAZ(3-(biphenyl-4-yl)-4-phenyl-5-tert-butylphenyl-1,2,4-triazole), NTAZ(4-(naphthalen-1-yl)-3,5-diphenyl-4H-1,2,4-triazole), tBu-PBD(2-(biphenyl-4-yl)-5-(4-tert-butylphenyl)-1,3,4-oxadiazole), and/or BAlq(bis(2-methyl-8-quinolinolato-N1,O8)-(1,1'-biphenyl-4-olato)aluminum).

In one or more embodiments, a hole injection layer may be further formed between the pixel electrode 250 and the hole transporting layer HTL. An electron injection layer may be further formed between a counter electrode 260 and the electron transporting layer ETL.

The counter electrode 260 may be arranged on the pixel defining film PDL and the light emitting layer EML. The counter electrode 260 may be formed on the electron transporting layer ETL.

The counter electrode 260 may be a common electrode that is commonly and continuously provided to the plurality of light emitting areas or pixels.

The counter electrode 260 may be provided as an electron injection electrode or a cathode. The counter electrode 260 may include a metal, an alloy, an electrically conductive compound, and/or the like, having a low work function.

For example, in one or more embodiments, the counter electrode 260 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, and/or the like. These may be used alone or in combination of two or more.

The counter electrode 260 may be provided as a transmissive electrode, a semi-transmissive electrode, or a reflective electrode. The counter electrode 260 may have a single-layer structure or a multi-layer structure.

A light emitting element EL may be defined by the laminated structure of the pixel electrode 250, the hole transporting layer HTL, the light emitting layer EML, the electron transporting layer ETL, and the counter electrode 260 described above. For example, in one or more embodiments, the light emitting element EL may be electrically connected to the transistor of each pixel through the drain electrode of the transistor.

The light emitting element EL may include a first light emitting element EL1, a second light emitting element EL2, and a third light emitting element EL3, respectively including a first light emitting layer EML1, a second light emitting layer EML2, and a third light emitting layer EML3. In one or more embodiments, the first light emitting element EL1, the second light emitting element EL2, and the third light emitting element EL3 may be provided as a red light emitting element, a green light emitting element, and a blue light emitting element, respectively.

An encapsulation layer TFE covering the light emitting elements EL1, EL2, and EL3 may be arranged on the counter electrode 260. The encapsulation layer TFE may be arranged on the pixel defining film PDL and the light emitting elements EL1, EL2, and EL3 to protect the light emitting elements EL1, EL2, and EL3 from moisture and/or oxygen.

The encapsulation layer TFE may include an inorganic film including: silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, and/or the like), an epoxy resin (e.g., aliphatic glycidyl ether (AGE)), or a combination thereof; or a combination of the inorganic film and the organic film.

The encapsulation layer TFE may be formed in a single-layer structure or a multi-layer structure. In one or more embodiments, the encapsulation layer TFE may have a sequentially laminated structure of a first inorganic layer, an organic layer, and a second inorganic layer.

Various functional layers that perform functions such as increasing luminance, controlling color, and preventing or reducing reflection may be formed on the encapsulation layer TFE.

According to one or more embodiments illustrated in FIG. 3, the first connection electrode 172 penetrates through the planarization layer 150, and the second connection electrode 212 is electrically connected to the first connection electrode 172. Therefore, it may approach the lower transistor TR1 through the second connection electrode 212. Accordingly, because it may approach the lower transistor TR1 independently of the upper transistor TR2, the degree of freedom in wirings may be increased.

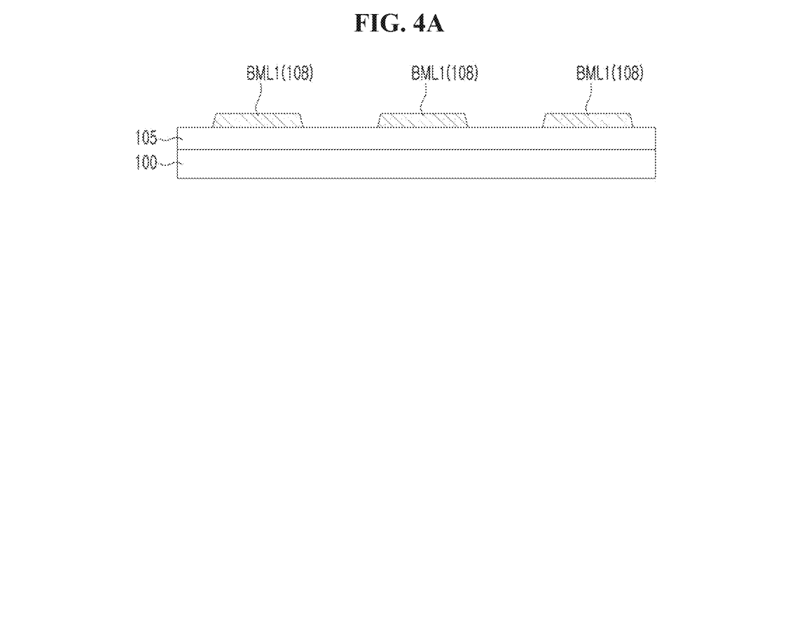

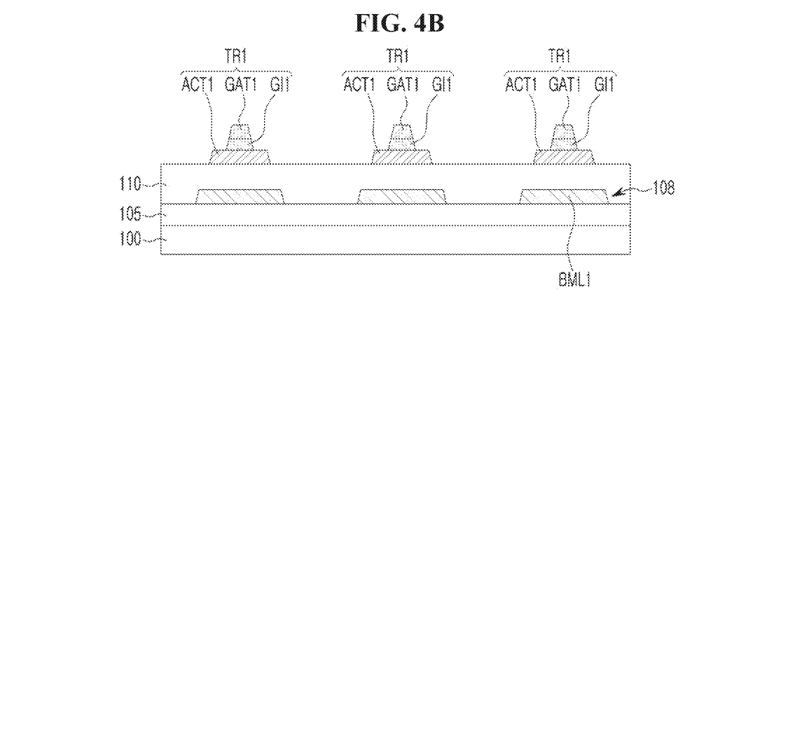

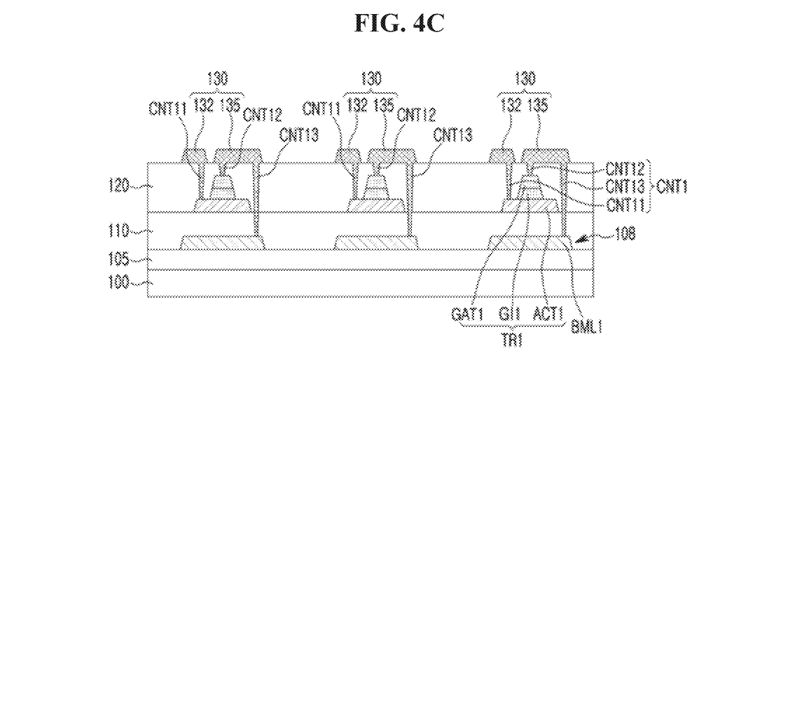

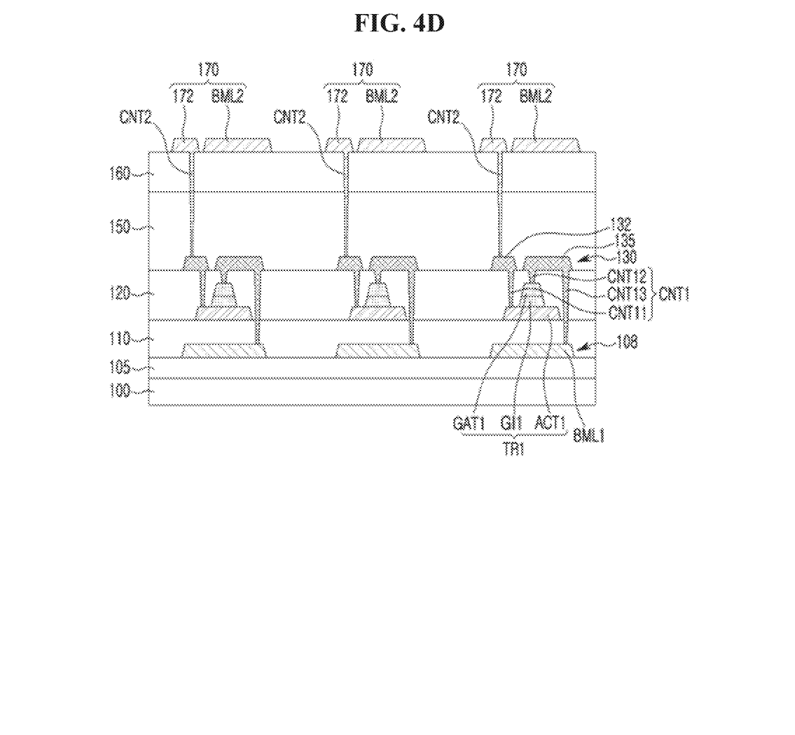

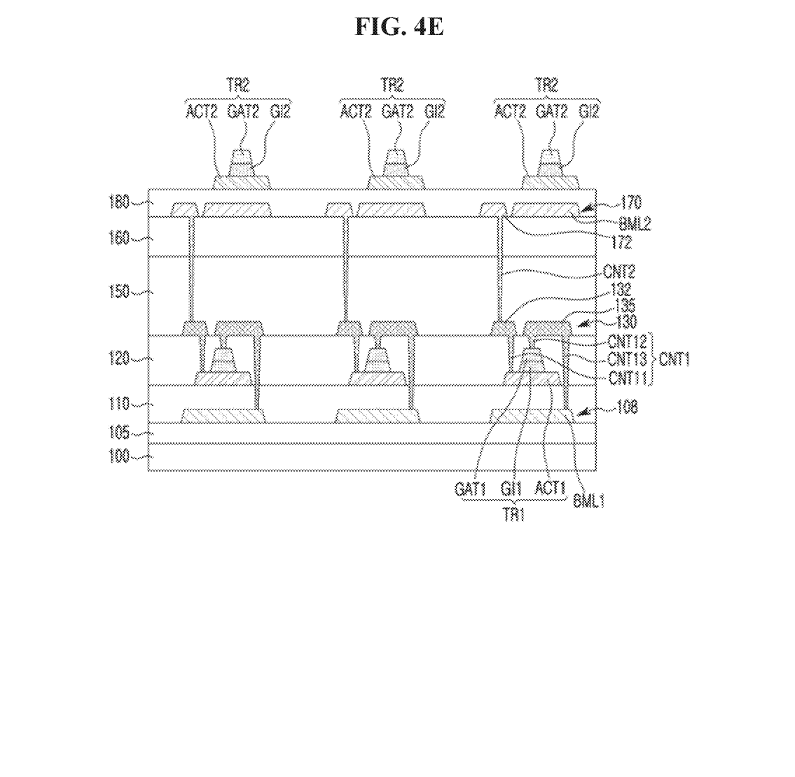

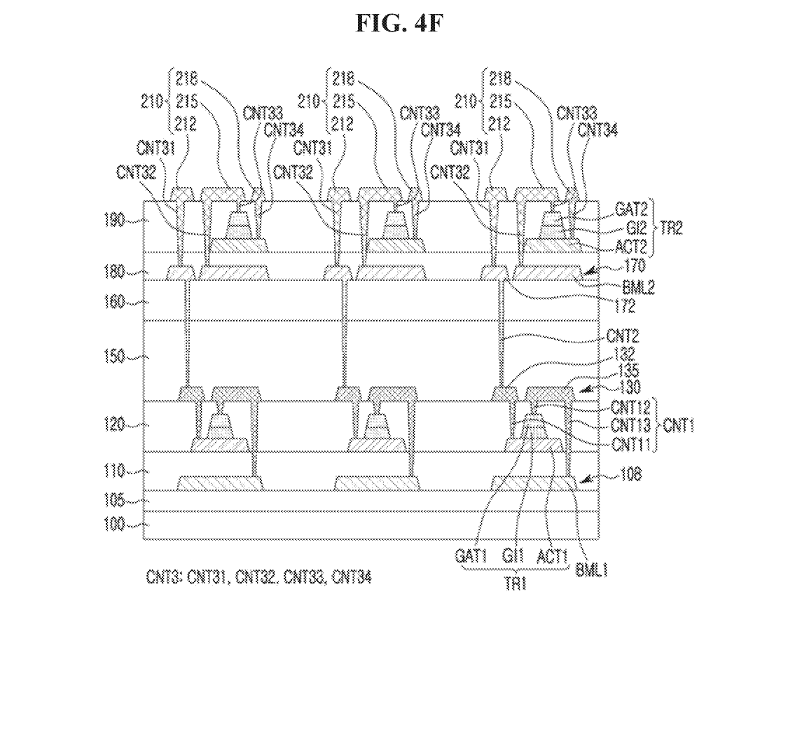

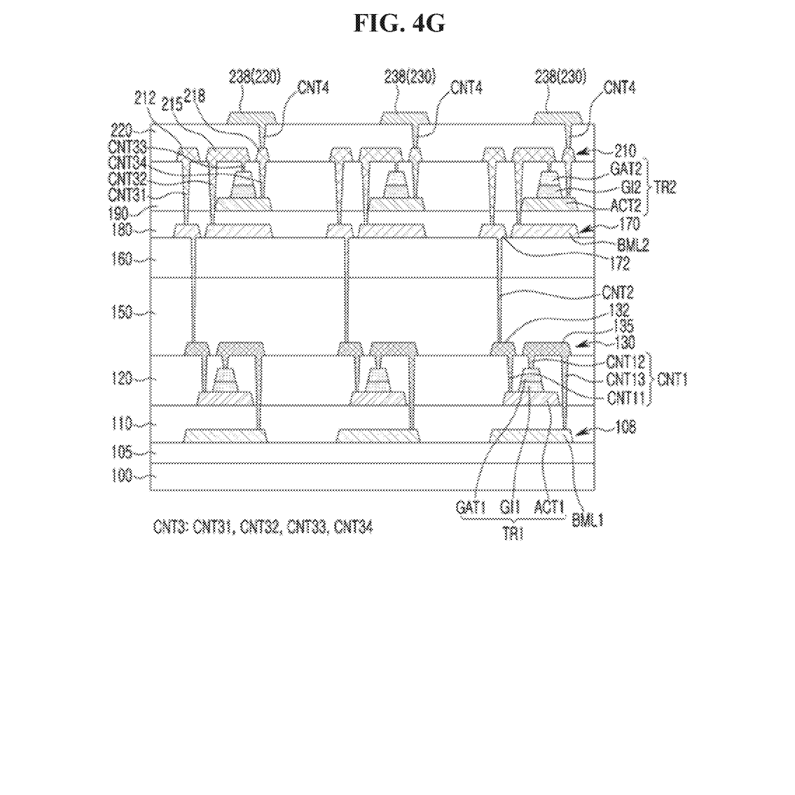

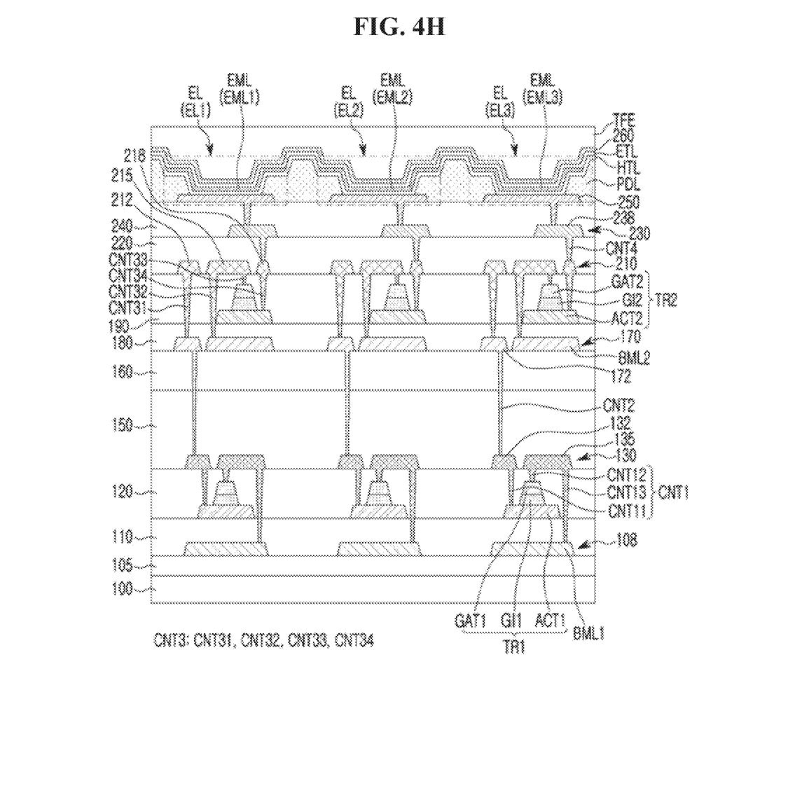

FIGS. 4A - 4H are views illustrating a manufacturing method of a display device according to one or more embodiments of the present disclosure. FIGS. 4A - 4H may illustrate a manufacturing method of the display device of FIG. 3 according to one or more embodiments. Hereinafter, the manufacturing method of a display device will be discussed in more detail with reference to FIGS. 4A - 4H in conjunction with FIG. 3.

Referring to FIG. 4A, first, a barrier layer 105 may be formed on a base substrate 100. The barrier layer 105 may be formed through a deposition process such as a chemical vapor deposition (CVD) process, a sputtering process, an atomic layer deposition (ALD) process, and/or the like.

A first lower conductive layer 108 including a first lower metal layer BML1 may be formed on the barrier layer 105. The first lower conductive layer 108 may be formed on the entire surface of the barrier layer 105, or may be formed only on a portion of the barrier layer 105 by patterning using a mask pattern.

Next, referring to FIG. 4B, a first buffer layer 110 is formed on the barrier layer 105 to cover the first lower conductive layer 108.

A lower transistor TR1 including an active layer ACT1, a gate insulating layer GI1, and a gate electrode GAT1 is formed on the first buffer layer 110. The active layer ACT1 may be patterned through a photolithography process to be repeatedly/regularly arranged for each pixel. Some areas of the active layer ACT1 of the lower transistor TR1 may be doped with p-type (kind) or n-type (kind) dopants. The gate insulating layer GI1 may be formed on the active layer ACT1 through a deposition process so as to partially cover or to continuously and commonly cover each of the active layers ACT1 (e.g., in a direction perpendicular to the ground, e.g., in a thickness direction).

In one or more embodiments, a source region and a drain region may be formed in the active layer ACT1 using the gate electrode GAT1 as an ion injection mask.

A first interlayer insulating layer 120 (see FIG. 4C) may be formed on the gate electrode GAT1 through a deposition process.

In one or more embodiments, if (e.g., when) the gate insulating layer GI1 of the lower transistor TR1 has an individual pattern shape and the active layer ACT1 includes an oxide semiconductor, hydrogen (H) contained in the first interlayer insulating layer 120 may be diffused or moved to the active layer ACT1 when forming the first interlayer insulating layer 120. Accordingly, as a carrier concentration increases due to hydrogen, the source region and the drain region may be formed on the side portions of the active layer ACT1.

Next, referring to FIG. 4C, a first connection electrode layer 130 may be formed on the first interlayer insulating layer 120. The first connection electrode layer 130 may include at least one of a first source/drain electrode 132 and a first gate connection electrode 135, and FIG. 4C illustrates that the first connection electrode layer 130 includes both (e.g., simultaneously) the first source/drain electrode 132 and the first gate connection electrode 135.

Contact holes CNT11, CNT12, and CNT13, constituting a contact hole CNT1 (see FIG. 3), may be formed by partially etching the first interlayer insulating layer 120 and, if necessary, the first buffer layer 110. For example, the contact holes CNT11, CNT12, and CNT13, which together constitute the contact hole CNT1 (see FIG. 3), may be formed. For example, in one or more embodiments, the contact hole CNT11 exposing the drain region of the lower transistor TR1 and the contact hole CNT12 exposing the gate electrode GAT1 of the lower transistor TR1 may be formed by etching the first interlayer insulating layer 120, and the contact hole CNT13 exposing the first lower metal layer BML1 may be formed by etching the first interlayer insulating layer 120 and the first buffer layer 110.

The first source/drain electrode 132 and the first gate connection electrode 135 may be formed by forming a metal layer that sufficiently fills the contact holes CNT11, CNT12, and CNT13 on the first interlayer insulating layer 120 and then partially etching the metal layer.

The gate electrode GAT1 of the lower transistor TR1 and the first connection electrode layer 130 may be formed through the above-described deposition process, such as the sputtering process.

Next, referring to FIG. 4D, a planarization layer 150 may be formed on the first interlayer insulating layer 120 to cover the first connection electrode layer 130. The planarization layer 150 may include an SOG material. The planarization layer 150 may be formed through a coating process such as a spin coating process or the deposition process described above.

A second interlayer insulating layer 160 may be formed on the planarization layer 150. The second interlayer insulating layer 160 may be formed through the deposition process described above.

A second lower conductive layer 170 including a first connection electrode 172 and a second lower metal layer BML2 may be formed on the second interlayer insulating layer 160. A contact hole CNT2 may be formed by partially etching the planarization layer 150 and the second interlayer insulating layer 160. The first connection electrode 172 and the second lower metal layer BML2 may be concurrently (e.g., simultaneously) formed by forming a metal layer that sufficiently fills the contact hole CNT2 on the second interlayer insulating layer 160 and then partially etching the metal layer.

According to the present configuration, because the first connection electrode 172 is concurrently (e.g., simultaneously) formed with the second lower metal layer BML2, the number of processes may be reduced compared to the case where the first connection electrode 172 and the second lower metal layer BML2 are separately formed. For example, in order to form the first connection electrode 172 separately from the second lower metal layer BML2, an additional process of applying and etching the material forming the first connection electrode 172 may be required.

Next, referring to FIG. 4E, a second buffer layer 180 may be formed on the second interlayer insulating layer 160 to cover the second lower conductive layer 170.

An upper transistor TR2 including an active layer ACT2, a gate insulating layer GI2, and a gate electrode GAT2 may be formed on the second buffer layer 180. Because the formation of the upper transistor TR2 is similar to that of the lower transistor TR1, a detailed description thereof is omitted for conciseness.

Next, referring to FIG. 4F, a third interlayer insulating layer 190 may be formed on the second buffer layer 180 to cover the upper transistor TR2. The third interlayer insulating layer 190 may be formed similarly as the formation of the first interlayer insulating layer 120.

Contact holes CNT3 (CNT31, CNT32, CNT33, and CNT34) may be formed by partially etching the third interlayer insulating layer 190 and/or the second buffer layer 180. The contact holes CNT31, CNT32, CNT33, and CNT34 may be connected to the first connection electrode 172, the second lower metal layer BML2, the gate electrode GAT2 of the upper transistor TR2, and the source region or drain region of the upper transistor TR2, respectively.

In this regard, the contact holes CNT3 - CNT31, CNT32, CNT33, and CNT34 - may be concurrently (e.g., simultaneously) formed. Because the first connection electrode 172 is formed on the second interlayer insulating layer 160 that is the same as the second lower metal layer BML2, a length of the contact hole CNT31 extending to the first connection electrode 172 is substantially the same as a length of the contact hole CNT32 extending to the second lower metal layer BML2.

In FIG. 3, a first connection electrode 172 is illustrated, whereas in FIG. 5 an alternative first connection electrode 155 is shown at a different level; both implement the connection scheme described herein. For example, as described below with reference to FIG. 5, in one or more embodiments, if (e.g., when) the first connection electrode 155 is positioned lower than the first connection electrode 172 in FIGS. 3 and 4F, with respect to the second lower metal layer BML2 or the upper transistor TR2, a length of the contact hole CNT31’ may be longer than the length of the contact hole CNT31 of FIGS. 3 and 4F. In FIGS. 3 and 4F, because the length of the contact hole CNT31 is relatively short, a deviation between the contact holes CNT31, CNT32, CNT33, and CNT34 in length is not large. Therefore, the contact holes CNT31, CNT32, CNT33, and CNT34 may be formed by a same etching process, for example, by an etching device having the same power. To form the contact holes CNT31, CNT32, CNT33, and CNT34, the power needs to be set to match the longest contact hole CNT31 or CNT32. Because the contact hole CNT33 is connected to the gate electrode GAT2, which is a metal, etching of the gate electrode GAT2 is almost non-existent, whereas the active layer ACT2 connected to the contact hole CNT34 may be excessively (or substantially) etched, resulting in defects. In embodiments of FIGS. 3 and 4F, because the deviation between the contact holes CNT31, CNT32, CNT33, and CNT34 in length is not large, the possibility of excessive etching of the active layer ACT2 is low, so that the contact holes CNT31, CNT32, CNT33, and CNT34 may be concurrently (e.g., simultaneously) formed.

A second connection electrode layer 210 including a second connection electrode 212, a second gate connection electrode 215, and a second source/drain electrode 218 may be formed by forming a metal layer that sufficiently fills the contact holes CNT3 on the third interlayer insulating layer 190 and then partially etching the metal layer.

Next, referring to FIG. 4G, a first via layer 220 may be formed on the third interlayer insulating layer 190 to cover the second connection electrode layer 210. A contact hole CNT4 may be formed by partially etching the first via layer 220. A third connection electrode layer 230 including a source/drain connection electrode 238 may be formed by forming a metal layer that sufficiently fills the contact hole CNT4 on the first via layer 220 and then partially etching the metal layer.

Next, referring to FIG. 4H, a second via layer 240 may be formed on the first via layer 220 to cover the third connection electrode layer 230.

The first via layer 220 and the second via layer 240 may be each formed through a coating process such as a spin coating process or the deposition process described above.

A via hole exposing an upper surface of the source/drain connection electrode 238 may be formed by partially etching the second via layer 240. A pixel electrode 250 may be formed by forming a conductive layer that sufficiently fills the via hole and includes a metal material and/or a transparent conductive oxide on an upper surface of the second via layer 240 and then etching the conductive layer. The pixel electrode 250 may include a via portion filling the via hole.

A pixel defining film PDL that exposes an upper surface of the pixel electrode 250 may be formed on the second via layer 240.

A hole transporting layer HTL, a light emitting layer EML, an electron transporting layer ETL, a counter electrode 260, and an encapsulation layer TFE may be sequentially formed on the pixel defining film PDL. The light emitting layer EML, the hole transporting layer HTL, and/or the electron transporting layer ETL may each be formed through processes such as thermal deposition, vapor deposition, vacuum deposition, spin coating, inkjet printing, laser printing, casting, laser thermal transfer, and/or the like. For example, in one or more embodiments, selective deposition for each pixel of the light emitting layer EML may be effectively performed by the pixel defining film PDL having the step structure.

FIG. 5 is a cross-sectional view of a display device according to one or more embodiments of the present disclosure.

A display device of FIG. 5 differs from the display device of FIG. 3 in that it includes a first connection electrode 155 instead of the first connection electrode 172. In the display device of FIG. 5, the first connection electrode 155 may be formed on a layer different from the second lower electrode layer 172, for example, on the planarization layer 150. Descriptions of other components shown in FIG. 5 may refer to the descriptions of the similar or same components illustrated in FIG. 3 and FIGS. 4A - 4H, and duplicated descriptions thereof are not repeated for conciseness.

In the display device of FIG. 5, the first connection electrode 155 penetrates through the planarization layer 150, and the second connection electrode 212 is electrically connected to the first connection electrode 155. Therefore, it may approach the lower transistor TR1 through the second connection electrode 212.

Accordingly, because it may approach the lower transistor TR1 independently of the upper transistor TR2, the degree of freedom in wirings may be increased.

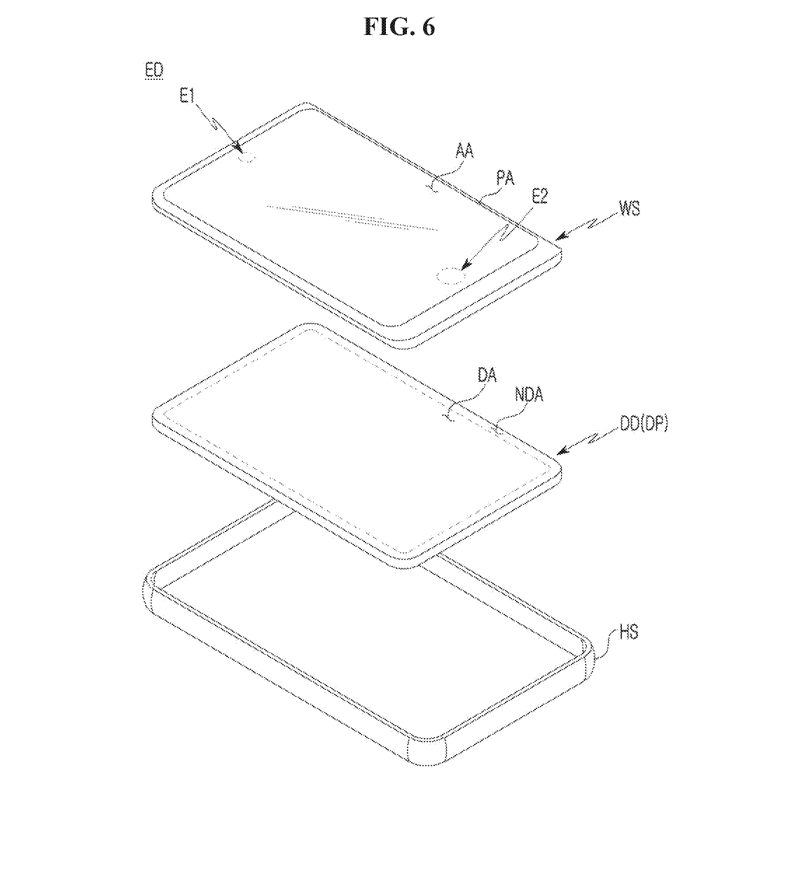

FIG. 6 is an exploded perspective view illustrating an electronic device according to one or more embodiments of the present disclosure.

According to one or more embodiments, an electronic device ED may be implemented in the form of a mobile phone (e.g., a smart phone), a tablet, a PC, and/or the like, including the display device described above.

Referring to FIG. 6, the electronic device ED may include a window structure WS, a display device DD, and a housing HS. The display device DD may include a display panel DP including the above-described transistor structures and light emitting element EL. The housing HS, the display device DD, and the window structure WS may be sequentially laminated along the third direction.

The window structure WS may provide an external display surface that is perceived by a user, such as a display surface of the electronic device ED, such as a viewing surface of the electronic device ED such as a mobile phone, and may include a transparent material film. For example, the window structure WS may include glass (e.g., ultra-thin glass (UTG)), a hard coating film, a plastic film, and/or the like.

An outer surface of the window structure WS may include an active area AA and a peripheral area PA. The active area AA may provide a surface on which an image of the display device DD is actually displayed and to which a user’s touch/command is input. The peripheral area PA may substantially correspond to a bezel area of the electronic device ED.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In one or more embodiments, functional element areas E1 and E2 may be included within the active area AA of the window structure WS. For example, in one or more embodiments, a first functional element area E1 may be included in one end of the active area AA and may be implemented in the form of a camera hole, and a second functional element area E2 may be provided at the other end of the active area AA as a fingerprint sensing area.

For example, in one or more embodiments, a sensor structure for touch sensing or fingerprint sensing may be arranged within the display panel DP or between the window structure WS and the display panel DP.

The housing HS may be provided as a chassis structure or a rear housing of the display device DD or the electronic device ED. In one or more embodiments, a cover panel may be arranged between the housing HS and the display panel DP. The housing HS or the cover panel may include a plate (e.g., a SUS plate) that supports the display panel DP, the printed circuit board 300 (see FIG. 1), and/or the like. The housing HS or the cover panel may further include an elastic body for shock absorption of the display device DD.

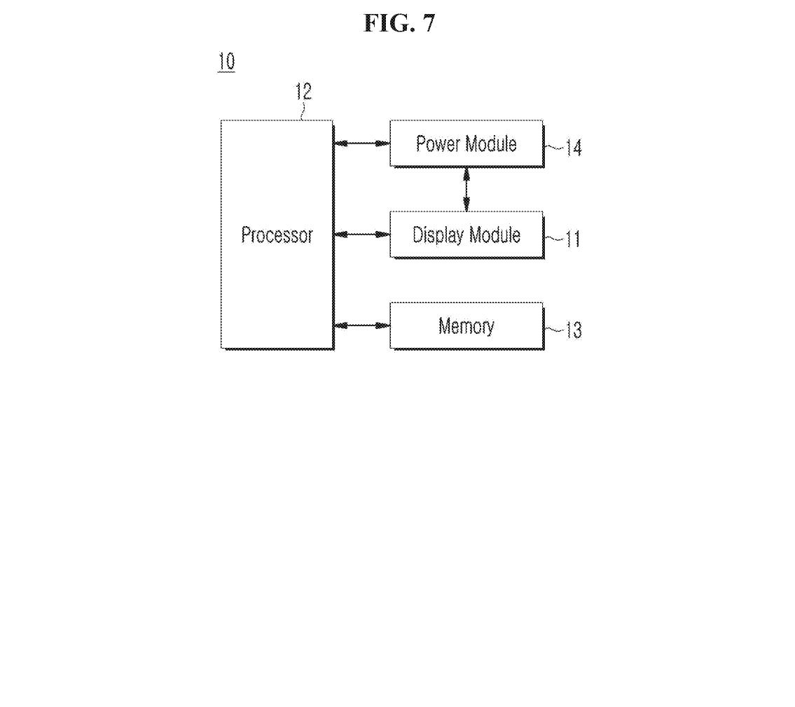

FIG. 7 is a block diagram of an electronic device according to one or more embodiments of the present disclosure.

Referring to FIG. 7, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information necessary for an operation of the processor 12 and/or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power desired or required for an operation of the electronic device 10.

At least one of the components of the electronic device 10 described above may be included in the display device according to one or more embodiments described above. In one or more embodiments, some of the individual modules functionally included within one module may be included within the display device, while others may be provided separately from the display device. For example, the display module 11 includes the display device, and the processor 12, the memory 13, and the power module 14 may be provided in the form of other devices within the electronic device 10 other than the display device.

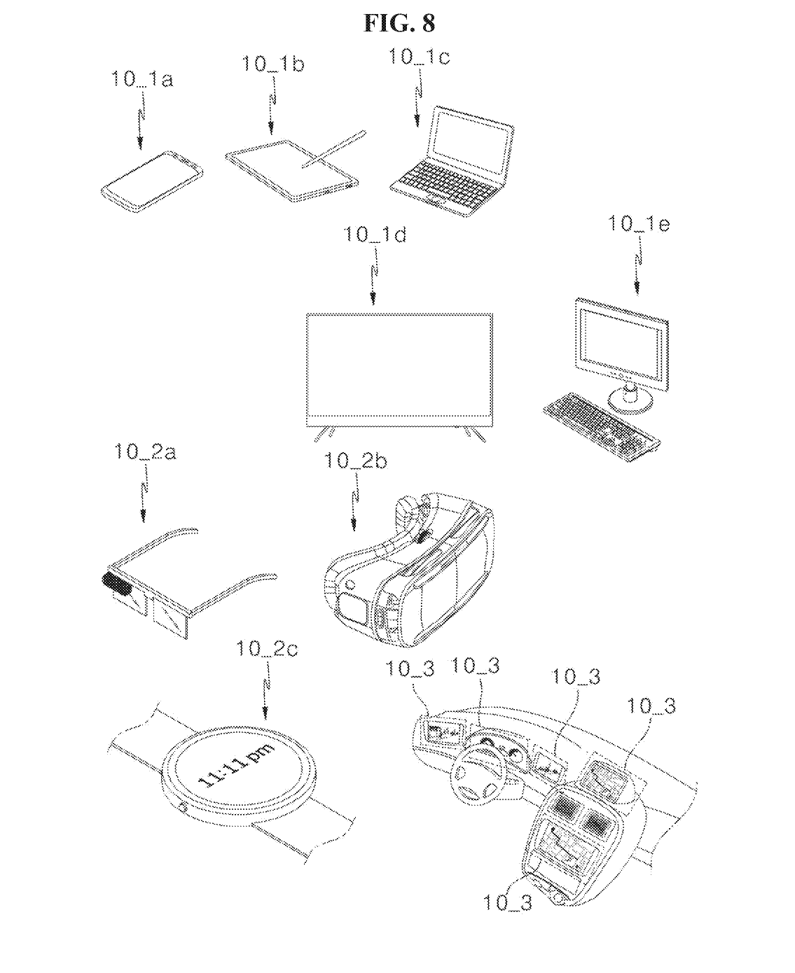

FIG. 8 illustrates schematic views of electronic devices according to one or more embodiments of the present disclosure.

Referring to FIG. 8, non-limiting examples of one or more suitable electronic devices to which the display device according to one or more embodiments of the present disclosure is applied may include: an image display electronic device such as a smart phone 10_1a, a tablet PC 10_1b, a laptop 10_1c, a TV 10_1d, and a desk monitor 10_1e; a wearable electronic device including a display module such as a smart glasses 10_2a, a head mounted display 10_2b, and a smart watch 10_2c; and a vehicle electronic device 10_3 including a display module such as a Center Information Display (CID), a room mirror display, and/or the like, arranged on a vehicle’s instrument panel, center fascia, or dashboard. In one or more embodiments, the electronic device may also include virtual reality glasses and/or augmented reality glasses.

In addition to the examples illustrated in FIG. 8, the disclosed display device architecture may be implemented in any electronic system that benefits from high-resolution, high-integration display panels. By employing a stacked transistor configuration with a conductive layer penetrating a planarization layer and electrically coupling lower and upper circuit elements, the embodiments described herein enable compact pixel circuits with improved wiring flexibility. This structural approach facilitates reduced bezel size, enhanced aperture ratio, and compatibility with various display technologies, including OLED, LCD, and emerging display types, thereby supporting a wide range of consumer, industrial, and automotive applications.

In this disclosure, it will be further understood that the terms "comprise(s)/comprising," "include(s)/including," and/or "have(has)/having," if (e.g., when) used in this disclosure, specify the presence of stated features, numbers, steps, operations, elements, components, and/or groups thereof, but do not preclude the presence or addition of one or more other features, numbers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

As used herein, the term "and/or" or “or” may include any and all combinations of one or more of the associated listed items. Expressions such as “at least one of,” “one of,” and “selected from,” when preceding a list of elements, modify the entire list of elements and do not modify the individual elements of the list. For example, "at least one of a, b, or c," “at least one selected from a, b, and c,” "at least one selected from among a to c," and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

As used herein, the singular forms, "a," "an," “one,” and "the" are intended to include the plural forms as well, unless the context clearly indicates otherwise. Further, the utilization of “may” when describing embodiments of the present disclosure refers to “one or more embodiments of the present disclosure".

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, ± 20%, ± 10%, or ± 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms "use," "using," and "used" may be considered synonymous with the terms "utilize," "utilizing," and "utilized," respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the electronic device, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In concluding the detailed description, those skilled in the art will appreciate that many variations and modifications may be made to the embodiments without substantially departing from the principles and teachings of the present disclosure. Therefore, the disclosed embodiments of the disclosure are used in a generic and descriptive sense only and not for purposes of limitation. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device, comprising:
a lower transistor;
a planarization layer on the lower transistor;
an upper transistor on the planarization layer;
an electrode layer on the upper transistor; and
a conductive layer between the planarization layer and the upper transistor and electrically connecting the lower transistor and the electrode layer.

2. The display device of claim 1, wherein the conductive layer comprises a first connection electrode that penetrates through the planarization layer and is electrically connected to the lower transistor.

3. The display device of claim 2, wherein the conductive layer further comprises a gate lower electrode electrically connected to a gate electrode of the upper transistor.

4. The display device of claim 2, further comprising an insulating layer on the upper transistor to cover the upper transistor,
wherein the electrode layer comprises a second connection electrode that penetrates through at least the insulating layer and is electrically connected to the first connection electrode.

5. The display device of claim 4, wherein the electrode layer further comprises a gate connection electrode having one side penetrating through the insulating layer and electrically connected to a gate electrode of the upper transistor.

6. The display device of claim 5, wherein the conductive layer further comprises a gate lower electrode that at least partially overlaps the upper transistor, and
the other side of the gate connection electrode penetrates through the insulating layer and is electrically connected to the gate lower electrode.

7. The display device of claim 4, wherein the electrode layer further comprises a drain electrode that penetrates through the insulating layer and is electrically connected to a drain region of the upper transistor.

8. The display device of claim 2, further comprising:
a lower insulating layer on the lower transistor to cover the lower transistor; and
a lower electrode layer on the lower insulating layer, covered by the planarization layer, and electrically connected to the lower transistor,
wherein the first connection electrode is electrically connected to the lower electrode layer.

9. The display device of claim 8, wherein the lower electrode layer comprises a lower drain electrode that penetrates through the lower insulating layer and is electrically connected to a drain region of the lower transistor.

10. The display device of claim 9, wherein the lower electrode layer further comprises a lower gate connection electrode having one side penetrating through the lower insulating layer and electrically connected to a gate electrode of the lower transistor.

11. The display device of claim 10, further comprising a second gate lower electrode having at least a portion arranged at a lower portion of the lower transistor to overlap the lower transistor,
wherein the other side of the lower gate connection electrode penetrates through the lower insulating layer and is electrically connected to the second gate lower electrode.

12. The display device of claim 1, wherein the planarization layer comprises a Spin On Glass (SOG) material.

13. A manufacturing method, comprising:
forming a lower transistor on a substrate;
forming a planarization layer on the lower transistor;
forming a conductive layer on the planarization layer, the conductive layer penetrating through the planarization layer and being electrically connected to the lower transistor;
forming an upper transistor on the conductive layer; and
forming an electrode layer electrically connected to the conductive layer on the upper transistor,
wherein the manufacturing method is a method of manufacturing a display device.

14. The manufacturing method of claim 13, wherein the forming of the conductive layer comprises:
forming a first contact hole penetrating through at least the planarization layer;
forming a first metal layer on the planarization layer to fill the first contact hole; and
forming the conductive layer by patterning the first metal layer, the conductive layer comprising a first connection electrode electrically connected to the lower transistor through a contact filling the first contact hole.

15. The manufacturing method of claim 14, wherein in the forming of the conductive layer by patterning the first metal layer, the first connection electrode and a gate lower electrode separated from the first connection electrode are formed by patterning the first metal layer.

16. The manufacturing method of claim 15, further comprising forming an insulating layer on the upper transistor to cover the upper transistor,
wherein the forming of the electrode layer comprises:
forming a plurality of contact holes penetrating through at least the insulating layer, the plurality of contact holes at least comprising a second contact hole extending to the gate lower electrode, a third contact hole extending to a gate electrode of the upper transistor, and a fourth contact hole extending to the first connection electrode;
forming a second metal layer on the insulating layer to fill the plurality of contact holes; and
forming the electrode layer by patterning the second metal layer, the electrode layer comprising a gate connection electrode electrically connected to the gate lower electrode through a contact filling the second contact hole and electrically connected to the gate electrode of the upper transistor through a contact filling the third contact hole, and a second connection electrode electrically connected to the first connection electrode by a contact filling the fourth contact hole.

17. The manufacturing method of claim 16, wherein in the forming of the plurality of contact holes, the plurality of contact holes comprise a fifth contact hole that penetrates through at least the insulating layer and extends to a drain region of the upper transistor, and
in the forming of the electrode layer by patterning the second metal layer, the electrode layer comprises a drain electrode electrically connected to the drain region of the upper transistor by a contact filling the fifth contact hole.

18. The manufacturing method of claim 14, further comprising:
forming a lower insulating layer on the lower transistor to cover the lower transistor;
forming a sixth contact hole penetrating through the lower insulating layer and extending to the lower transistor;
forming a third metal layer on the lower insulating layer to fill the sixth contact hole; and
forming a lower transistor connection electrode electrically connected to the lower transistor by patterning the third metal layer,
wherein the first contact hole extends to the lower transistor connection electrode.

19. An electronic device, comprising:
a display device;
a memory; and
a processor configured to control an operation of the display device by executing data stored in the memory,
wherein the display device comprises:
a lower transistor;
a planarization layer on the lower transistor;
an upper transistor on the planarization layer;
an electrode layer on the upper transistor; and
a conductive layer between the planarization layer and the upper transistor and electrically connecting the lower transistor and the electrode layer.

20. The electronic device of claim 19, wherein the electronic device comprises at least one of virtual reality or augmented reality glasses, a smartphone, a tablet PC, a laptop, a TV, a desk monitor, smart glasses, a head-mounted display, a smart watch, or a vehicle display.
